(19) United States
(12) Patent Application Publication
(10) Pub. No.: US 2012/0258654 A1
(43) Pub. Date: Oct. 11, 2012

(54) CONTAINER DATA CENTER

(75) Inventors: WEN-TANG PENG, Tu-Cheng (TW); YI-LIANG HSIAO, Tu-Cheng (TW)

(73) Assignee: HON HAI PRECISION INDUSTRY CO., LTD., Tu-Cheng (TW)

(21) Appl. No.: 13/178,524

(22) Filed: Jul. 8, 2011

(30) Foreign Application Priority Data
Apr. 8, 2011 (TW) 100112358

(51) Int. Cl. H05K 5/02

(52) U.S. Cl. 454/184

(57) ABSTRACT

A container data center includes a first container installed with a plurality of servers, and at least one cold air inlet and at least one hot air outlet are defined on the first container. The container data center further includes a second container installed with a cooling system, and at least one hot air inlet and at least one cold air outlet are defined on the second container. Cold air flows from the second container to the first container through the cold air outlet and the cold air inlet, and hot air flows from the first container to the second container through the hot air outlet and the hot air inlet. The cold air is generated from the cooling system and becomes the hot air after flowing through the servers and removing heat generated from the servers. The cooling system removes heat of the hot air and generates the cold air.

### BACKGROUND

1. Technical Field

The present disclosure relates to a data center, and particularly, to a container data center.

2. Description of Related Art

Container data centers are portable and far easier to set up than a traditional data center, and thus are widely used for data storing and computing. However, for a container data center with a large number of servers inside, cooling is a major issue in designing the container data center.

Therefore, what is needed is a container data center with robust cooling capability.

### BRIEF DESCRIPTION OF THE DRAWINGS

The components in the drawings are not necessarily drawn to scale, the emphasis instead being placed upon clearly illustrating the principles of a container data center with robust cooling capability. Moreover, in the drawings, like reference numerals designate corresponding parts throughout the several views.

FIG. 1 is an isometric, cutaway view showing a server container and a cooling container of a container data center in accordance with an exemplary embodiment.

FIG. 2 is an isometric view showing the server container of FIG. 1

FIG. 3 is an assembled, isometric and cutaway view of the container data center of FIG. 1.

FIG. 4 is a cross section of FIG. 3, taken along line IV-IV thereof.

### DETAILED DESCRIPTION

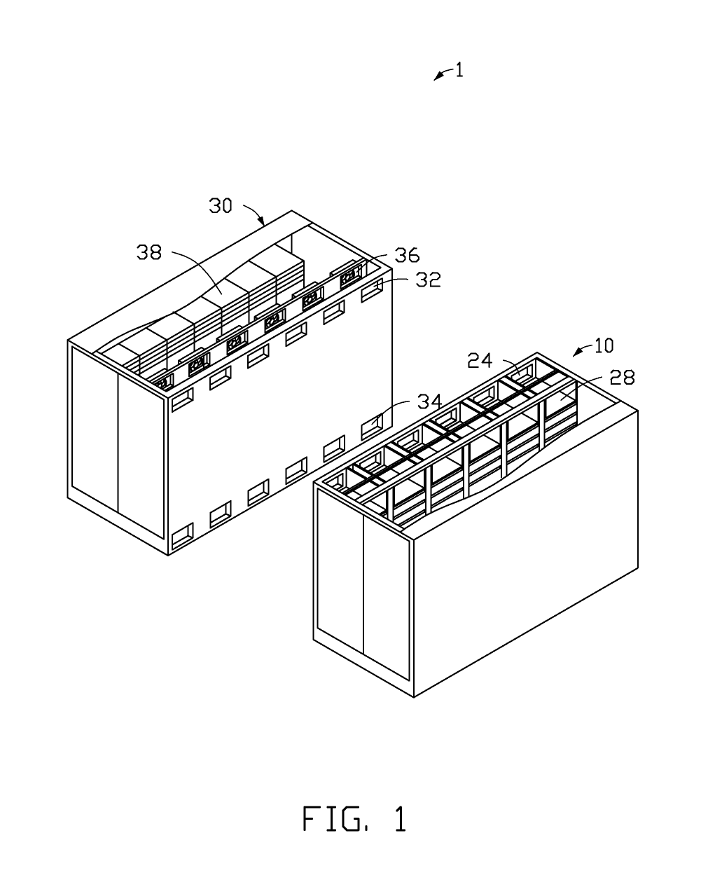

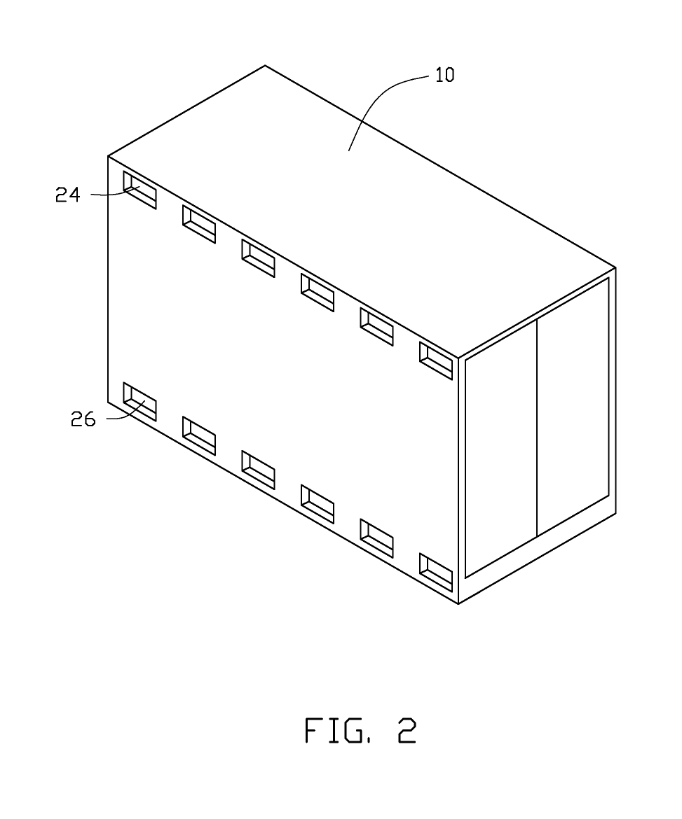

Referring to FIG. 1-2, in the present embodiment, a container data center 1 includes a server container 10 and a cooling container 30.

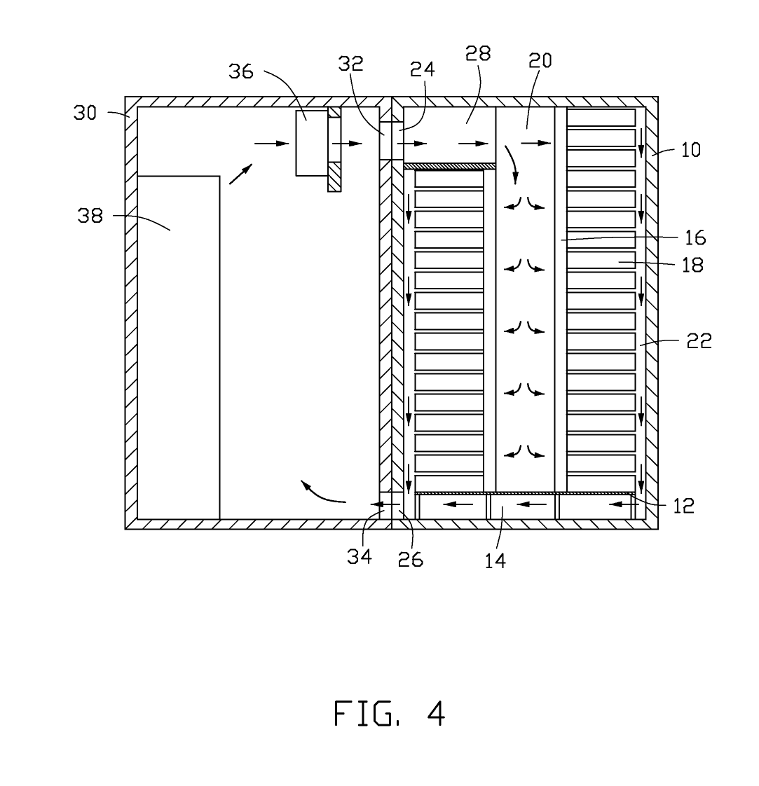

Referring to FIG. 4, a raised floor 12 is installed in the bottom of the server container 10 to form a bottom aisle 14 between the raised floor 12 and the bottom of the server container 10. On the raised floor 12, two rows of server racks 16 are respectively placed near two side walls of the server container 10, and a number of servers 18 are placed from top to bottom in the server racks 16. A middle aisle 20 is formed between the two rows of server racks 16, and a side aisle 22 is formed between the side wall and each row of server racks 16. A number of cold air inlets 24 are positioned on one of the side walls, and a number of hot air outlets 26 are position the bottom of the side wall. Top aisles 28 are positioned between the cold air inlets 24 and the middle aisle 20.

A number of cold air outlets 32 are positioned on the top of a side wall of the cooling container 30, and a number of hot air inlets 34 are positioned on the bottom of the side wall of the cooling container 30. A number of fans 36 are installed in the cooling container 30, and aligned to the cold air outlets 32. A cooling system 38 is installed inside the cooling container 30. In the present embodiment, the cooling system 38 is an air conditioner.

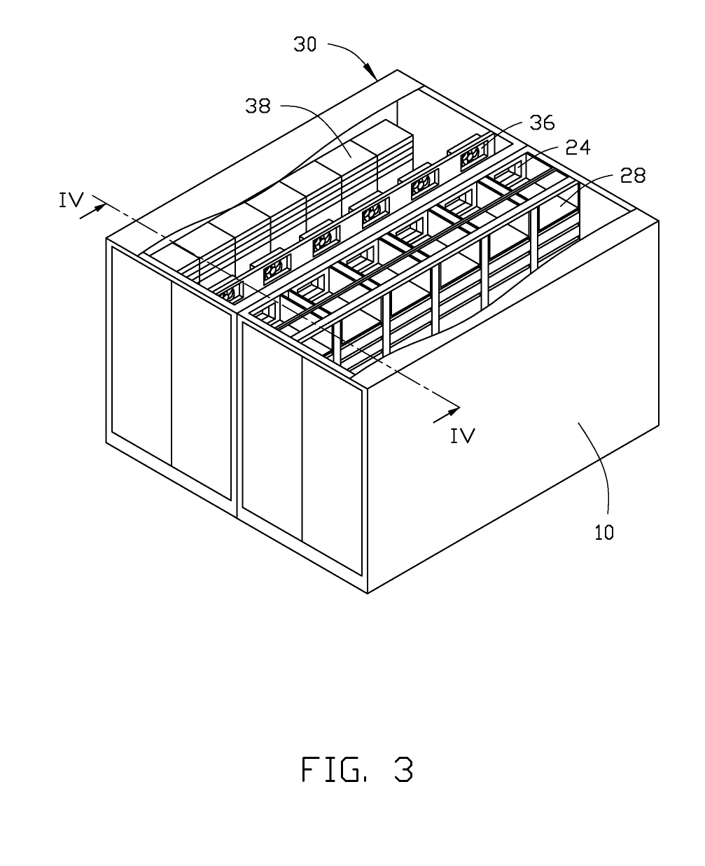

Referring to FIG. 3, when assembled, the cold air outlets 32 and the hot air inlets 34 of the cooling container 30 are aligned to the cold air inlets 24 and the hot air outlets 26 of the server container 10 respectively.

Referring to FIG. 4, the fans of the cooling container 30 blow the cold air generated by the cooling system 38 to the server racks 16 of the server container 10 through the cold air outlets 32, the cold air inlets 24, the top aisles 28, and the middle aisle 20. The cold air enters the side aisles 22 through the server racks 16 to remove heat from the server racks 16 while the cold air flows from top to bottom in the middle aisle 20. The cold air becomes hot air after flowing through the server racks 16, and flows to the cooling system 38 of the cooling container 30 through the side aisle 22, the bottom aisle 14, the hot air outlets 26, and the hot air inlets 34. The cooling system 38 removes heat from the hot air and generates the cold air to flow into the server container 10.

When the servers 18 and the cooling system 38 of the container data center 1 is installed into different containers, the heat generated by the servers 18 is removed and taken to the cooling container 30, and heat generated by the cooling system 38 itself is separated from the server container 10 to avoid affecting the temperature of the server container 10 to allow fast cooling of the servers 18.

In other embodiments, air ducts can be used to connect the cold air outlets 32 with the cold air inlets 24, or the hot air inlets 34 with the hot air outlets 26; the cold air outlets 32 and the hot air inlets 34 can be positioned in any position on the sidewalls of the cooling container 30; the hot air outlets 26 and the cold air inlets 24 can be positioned in any position on the sidewalls of the server container 10.

Although the present disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. A container data center, comprising:
a first container installed with a plurality of servers; at least one cold air inlet and at least one hot air outlet being defined on the first container; and
a second container installed with a cooling system; at least one hot air inlet and at least one cold air outlet being defined on the second container; cold air to be flowed from the second container to the first container through the cold air outlet and the cold air inlet; hot air to be flowed from the first container to the second container through the hot air outlet and the hot air inlet.

2. The container data center as claimed in claim 1, wherein the cold air is generated from the cooling system; the cold air becomes the hot air after flowing through the servers and removing heat generated from the servers; the cooling system removes heat of the hot air and generates the cold air.

3. The container data center as claimed in claim 2, wherein the servers are placed in row and a side aisle is formed between the servers and a side wall of the first container; the hot air flows form the servers to the hot air outlet through the side aisle.

4. The container data center as claimed in claim 3, wherein the servers are place on a raised floor installed above bottom of the first container to form a bottom aisle between the raised floor and the bottom of the first container; the cold air flows from the side aisle to the hot air outlet through the bottom aisle.

5. The container data center as claimed in claim 4, wherein the servers are placed in two rows to form a middle aisle between the two rows of servers; the hot air flows from the cold air inlet to the servers through the middle aisle.

6. The container data center as claimed in claim 5, wherein a top aisle is installed between the middle aisle and the cold air inlet; the hot air flows from the cold air inlet to the middle aisle through the top aisle.

7. The container data center as claimed in claim 3, wherein the servers placed in row are installed in server racks.

8. The container data center as claimed in claim 1, wherein at least one fan are installed to blow the cold air to the first container.

9. The container data center as claimed in claim 1, wherein the cooling system is an air conditioner.

10. The container data center as claimed in claim 1, wherein the first container and the second container are assembled side by side.

11. The container data center as claimed in claim 1, wherein the hot air inlet and the cold air outlet are connected with the hot air outlet and the cold air inlet respectively with air ducts.
